(19) United States
(12) Patent Application Publication
(10) Pub. No.: US 2012/0220129 A1
(43) Pub. Date: Aug. 30, 2012

(54) METHOD FOR FORMING MASK FOR FORMING CONTACT HOLES OF SEMICONDUCTOR DEVICE

(76) Inventor: Hee-Youl LIM, Gyeonggi-do (KR)

(21) Appl. No.: 13/333,680

(22) Filed: Dec. 21, 2011

(30) Foreign Application Priority Data
Feb. 28, 2011 (KR) 10-2011-0017899

(51) Int. Cl. H01L 21/312

(52) U.S. Cl. 438/694; 257/E21.259

(57) ABSTRACT

A method for forming a mask for forming contact holes of a semiconductor device includes coating an etch target layer with a first photoresist layer, patterning the first photoresist layer in a type of lines and spaces to form a first photoresist pattern, wherein the first photoresist pattern comprises pads formed at both ends of the first photoresist pattern, and lines repeatedly formed between the pads at the both ends, forming a protective layer on a surface of the first photoresist pattern by performing a freezing process onto the first photoresist pattern, and forming a second photoresist pattern having a type of lines stretched in a second direction which is perpendicular to the first direction on the etch target layer including the protective layer.

### CROSS-REFERENCE TO RELATED APPLICATIONS

The present application claims priority of Korean Patent Application No. 10-2011-0017899, filed on Feb. 28, 2011, which is incorporated herein by reference in its entirety.

### BACKGROUND

1. Field

Exemplary embodiments of the present invention relate to a semiconductor device fabrication technology, and more particularly, to a method for forming a mask for forming contact holes of a semiconductor device.

2. Description of the Related Art

As the integration degree of a semiconductor device increases, diverse lithography methods for forming fine patterns on a wafer are suggested recently. Among the lithography methods is a Double Patterning technology. Double patterning technology is expected to be applicable to the formation of pattern of less than about 40 nm along with extreme ultraviolet (EUV) ray exposure technology. The double patterning technology is divided into lithography-etch-lithography-etch (LELE) method and a lithography-freezing-lithography-etch (LFLE) method according to the number of times of performing an etch process. Whereas the etch process is performed twice in the LELE method, the LFLE method is drawing attention to the researchers and the industry in that the etch process is performed only once in the LFLE method.

To briefly describe the method of forming patterns of a semiconductor device using the double patterning technology of the LFLE method, first, a first photoresist layer is applied to a target pattern layer. A first photoresist pattern, that exposes a portion of the target pattern layer, is then formed by performing an exposure process and a development process onto the first photoresist layer by using a photo mask. A freezing material layer is applied to the resultant substrate structure and then a baking process is performed. As a result, a hard polymer layer is formed on the surface of the first photoresist pattern. Second, after the freezing material layer is removed, a second photoresist layer is applied to the substrate structure. A second photoresist pattern is then formed between the vacant spaces of the first photoresist pattern by performing an exposure process and a development process by using a photo mask. The exposed portions of the target pattern layer is removed by using the first photoresist pattern and the second photoresist pattern and performing an etch process. As a result, fine-pitch hole pattern may be formed.

As above-described, because the hard polymer layer is formed on the surface of the first photoresist pattern in LFLE method, the first photoresist pattern may be protected from being affected during the exposure process is carried out to form the second photoresist pattern.

However, in the conventional LFLE method, a sufficient protective layer may not be formed in a wide region since the edge of a cell region is not exposed and in the region, a material, e.g., a photo acid generator (PAG), decomposed by the exposure exists in a relatively low concentration. Therefore, since the region unexposed during the formation of the first photoresist pattern is exposed by the exposure process for forming the second photoresist pattern, an abnormal pattern may be formed.

FIG. 1 is a top view describing features of the conventional LFLE method.

Referring to FIG. 1, an abnormal hole pattern 20 is shown on the edge of a cell region. As described, the edge of the cell region may not be exposed during the formation of the first photoresist pattern and thus a protective layer is not sufficiently formed thereon. The unexposed region may be then exposed during a subsequent exposure process for forming the second photoresist pattern to possibly form the abnormal hole pattern.

The abnormal hole pattern may causes an adverse effect on the characteristics of a semiconductor device because the abnormal hole pattern may allow underlayer to be undesirably etched in a subsequent etch process.

### SUMMARY

An exemplary embodiment of the present invention is directed to a method for forming a mask for forming contact holes of a semiconductor device that may form a sufficient protective layer by performing a freezing process after a photoresist pattern is formed.

Another exemplary embodiment of the present invention is directed to a method for forming a mask for forming contact holes of a semiconductor device that may prevent the formation of an abnormal pattern.

In accordance with an exemplary embodiment of the present invention, a method for forming a mask for forming contact holes of a semiconductor device includes coating an etch target layer with a first photoresist layer, patterning the first photoresist layer in a type of lines and spaces to form a first photoresist pattern, where the first photoresist pattern comprises pads formed at both ends of the first photoresist pattern, and lines repeatedly formed between the pads at the both ends, forming a protective layer on a surface of the first photoresist pattern by performing a freezing process onto the first photoresist pattern, and forming a second photoresist pattern having a type of lines stretched in a second direction which is perpendicular to the first direction on the etch target layer including the protective layer.

In accordance with an exemplary embodiment of the present invention, a method for forming a mask for forming contact holes of a semiconductor device, comprise forming a first photoresist pattern on an etch target layer, wherein the first photoresist pattern comprises pads formed at both ends of the first photoresist pattern, and the width of the pads is controlled to be equal to or less than twice a penetration range of the freezing material layer, forming a protective layer on a surface of the first photoresist pattern, and forming a second photoresist pattern having a type of lines stretched in a second direction which is perpendicular to the first direction on the etch target layer including the protective layer.

### BRIEF DESCRIPTION OF THE DRAWINGS

FIG. 1 is a top view illustrating features of a conventional lithography-freezing-lithography-etch (LFLE) method,

FIGS. 2A to 2C are perspective views showing a method for forming a mask for forming contact holes of a semiconductor device in accordance with an exemplary embodiment of the present invention.

FIGS. 3A to 3C are plan views describing a method for forming a mask for forming contact holes of a semiconductor device in accordance with an exemplary embodiment of the present invention.

FIGS. 4A to 4D are cross-sectional views illustrating a method for forming a mask for forming contact holes of a semiconductor device in accordance with an exemplary embodiment of the present invention.

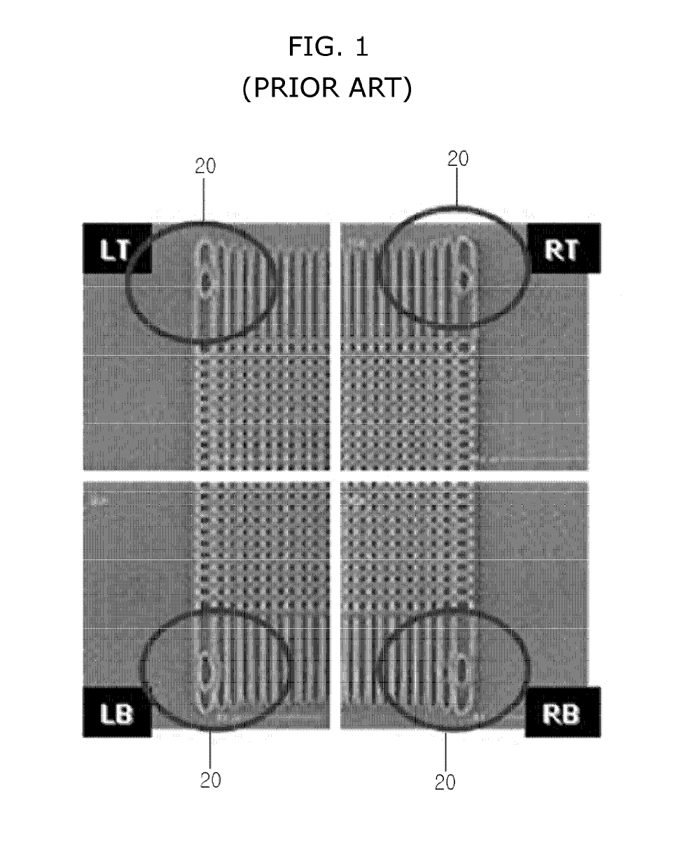

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The present invention provides a method of preventing the formation of an undesired hole pattern. The undesired hole pattern may be caused as an undesired region is exposed in an exposure process after the formation of a photoresist pattern due to incomplete freezing. The freezing is a process where an exposure process is performed but a development process is not performed. Specifically, a freezing material penetrates into the space between the molecules of a photoresist layer so as to form a protective layer on the surface of the photoresist layer which protects the photoresist layer from the light radiated during an exposure process or a solvent of a second photoresist layer.

Meanwhile, when a photoresist pattern is formed, a material, referred to as a photo acid generator (PAG) and decomposed through an exposure process, exists in a relatively low concentration in a wide region that is not exposed. Thus, the space into which a freezing material may penetrate may be insufficient in the inside of the photoresist layer and it may become difficult to form a sufficient protective layer.

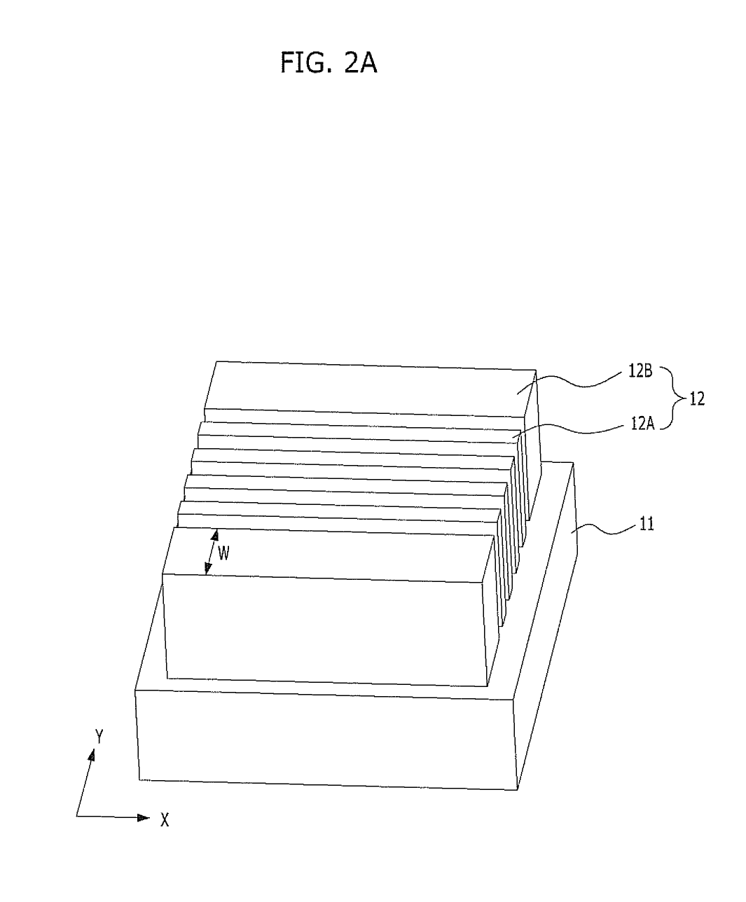

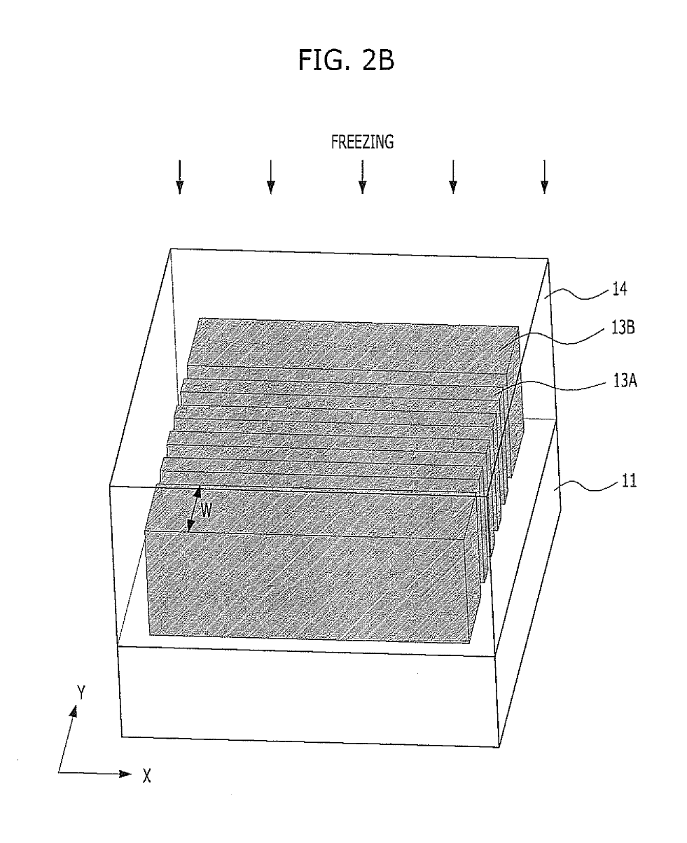

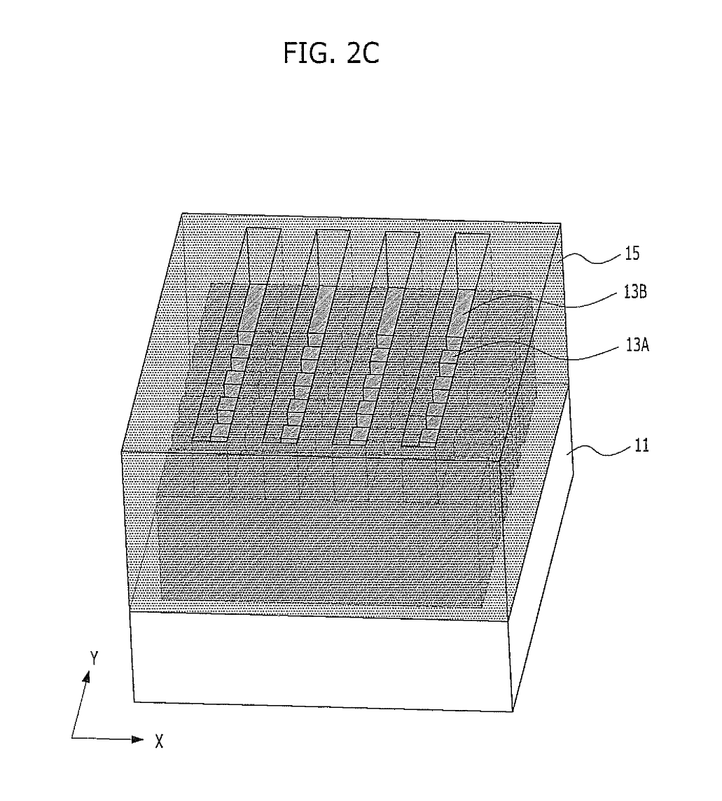

To address to the features, an exemplary embodiment of the present invention discloses a method of forming a sufficient protective layer by forming pads on the edge of the photoresist pattern so as to expose a region that is not exposed according to the conventional technology. This is described in detail with reference to FIGS. 2A to 4C.

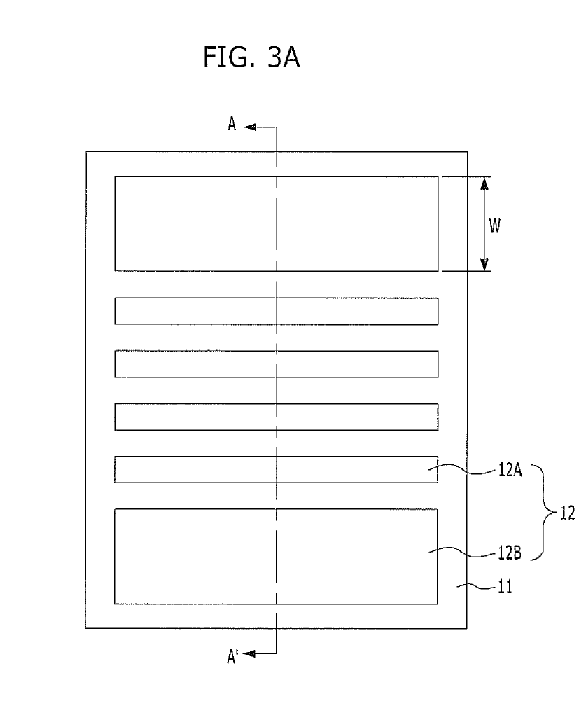

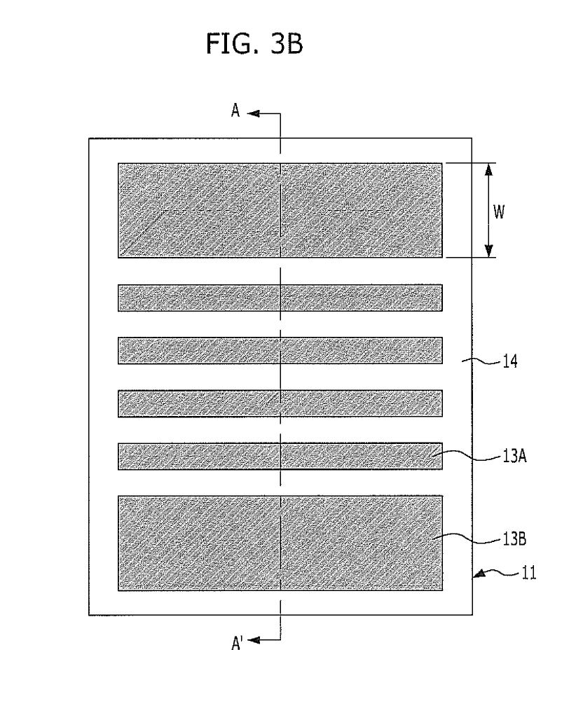

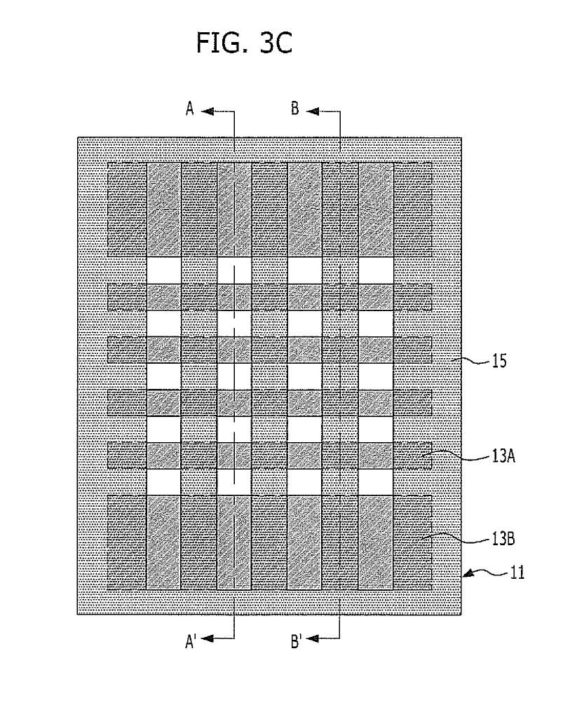

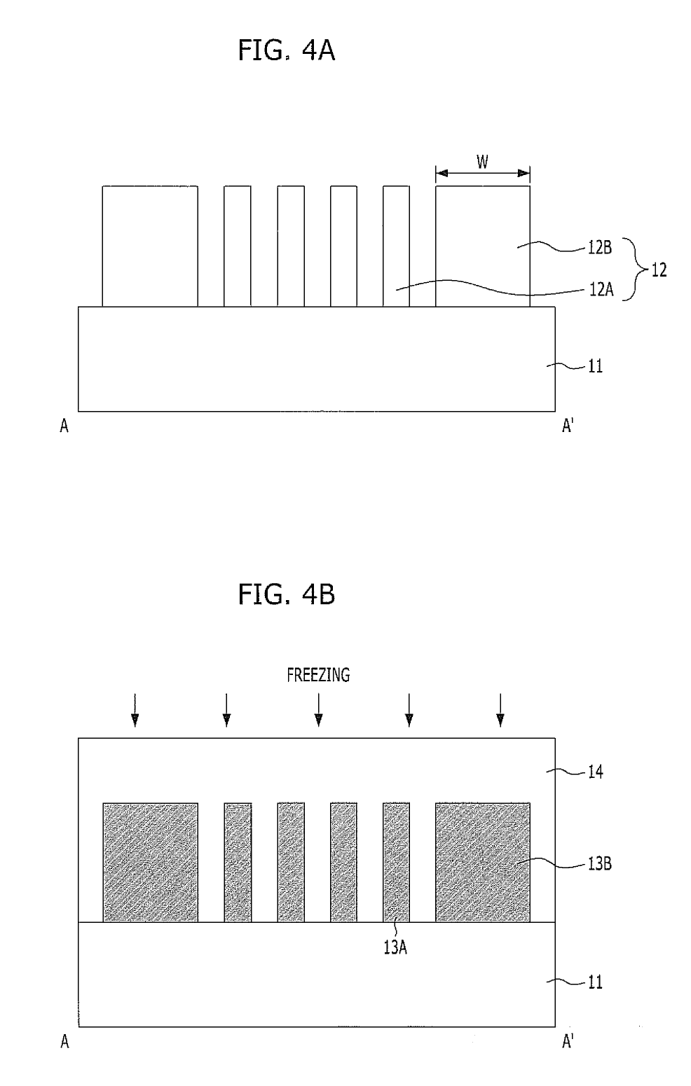

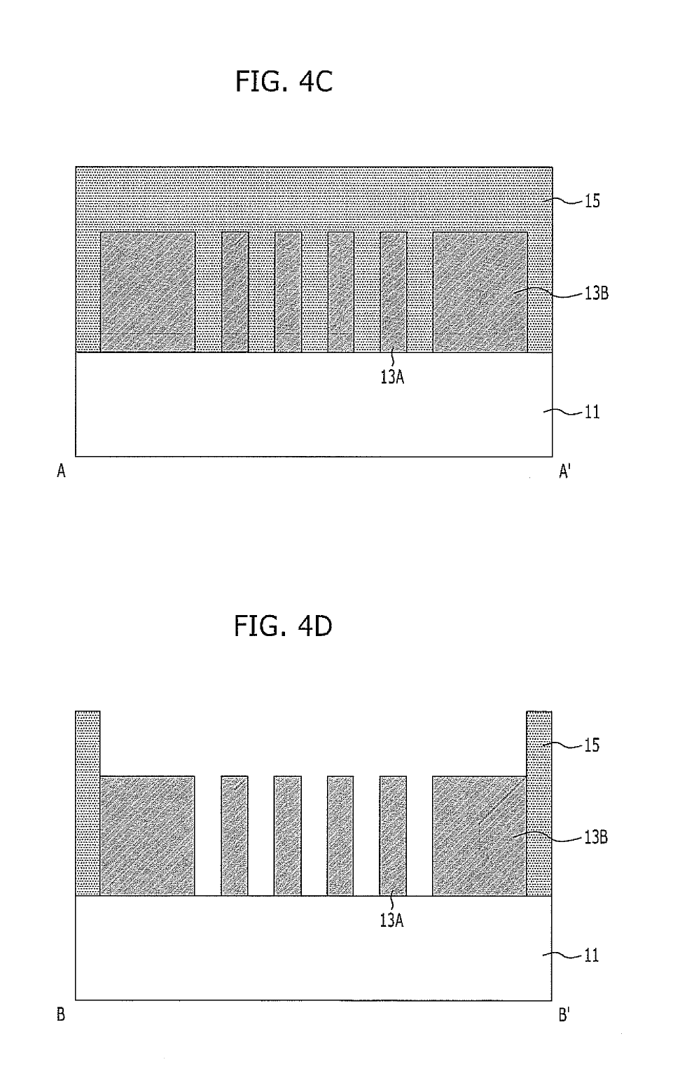

FIGS. 2A to 2C are perspective views illustrating a method for forming a mask for forming contact holes of a semiconductor device in accordance with an exemplary embodiment of the present invention. FIGS. 3A to 3C are plan views showing a method for forming a mask for forming contact holes of a semiconductor device in accordance with an exemplary embodiment of the present invention. FIGS. 4A to 4D are cross-sectional views illustrating a method for forming a mask for forming contact holes of a semiconductor device in accordance with an exemplary embodiment of the present invention. FIG. 4C is a cross-sectional view taken in the direction A-A′ shown in FIG. 3, and FIG. 4D is a cross-sectional view taken in the direction B-B′ shown in FIG. 3.

The structures of FIGS. 2A to 2C may be divided in an X direction and a Y direction. For the illustrative purpose, the X direction is referred to as a first direction, and the Y direction is referred to as a second direction. For the sake of convenience, the descriptions will be made by referring to FIGS. 2A to 2C, FIGS. 3A to 3C, and FIGS. 4A to 4D together.

Referring to FIGS. 2A, 3A and 4A, a first photoresist pattern 12 is formed over an etch target layer 11. The etch target layer 11 may be a target pattern layer or a hard mask layer. Also, before the first photoresist pattern 12 is formed, an anti-reflection layer (not shown) for preventing reflection may be formed over the etch target layer 11.

The first photoresist pattern 12 is formed by coating the etch target layer 11 with the first photoresist layer and performing a patterning process through exposure and development. The first photoresist pattern 12 is formed in the type of lines and spaces. The lines and the spaces stretched in the first direction, which is the X axial direction, are arrayed repeatedly.

In particular, the first photoresist pattern 12 comprises pads 12B formed at both ends of the first photoresist pattern 12, and lines 12A repeatedly formed between the pads 12B at the both ends. Here, the pads 12B are patterned thicker in a width W than the lines 12A. The patterning process is carried out in such a manner that the other portion of the first photoresist layer except the lines 12A and the pads 12B is removed. In other words, the lines 12A and the pads 12B are formed and the first photoresist layer in the other region is removed, and the remaining first photoresist pattern 12 becomes a photo acid generation region so that a protective layer is formed on the entire surface of the first photoresist pattern 12 in the subsequent freezing process.

For example, the width W of the pads 12B may be decided as a width that a freezing material may penetrate. When it is assumed that the curing penetration range of the freezing material ranges from approximately 200 nm to approximately 400 nm, the pads 12B may be formed to have a width W ranging from approximately 400 nm to approximately 800 nm, which is twice as wide as the curing penetration range of the freezing material, because the freezing material penetrates from both sides of a pad.

As illustrated in FIGS. 2B, 3B and 4B, a freezing material layer is formed over the substrate structure including the first photoresist pattern 12 (see FIG. 2A). The freezing material layer 14 may be formed by applying a freezing agent which is formed of a resin and a cross-linker. For example, the freezing agent may be a liquid polymer.

Subsequently, a baking process is performed. Through the baking process, the polymers included in the freezing material layer 14 participates in a cross-linking chemical reaction with the acid component of the first photoresist pattern 12 to thereby form a hard polymer 13A and 13B on the surface of the first photoresist pattern 12. The polymer 13A and 13B is not affected by an exposure process in the subsequent process of forming a second photoresist pattern. Hereafter, the polymer 13A and 13B is referred to as a protective layer 13A and 13B.

Particularly, the pads 12B are formed at both ends of the first photoresist pattern 12 to have a width that the freezing material layer 14 may penetrate by forming a photo acid generation region. Accordingly, the protective layer 13A and 13B is formed such a manner that the entire first photoresist pattern 12 is hardened.

As illustrated in FIGS. 2C, 3C and 4D, a development process is performed to remove the freezing material layer 14 (see FIG. 2B). Since the freezing material layer 14 (see FIG. 2B) is removed, the protective layer 13A and 13B formed of a hard polymer is exposed on the etch target layer 11.

Subsequently, a second photoresist pattern 15 is formed over the etch target layer 11 including the protective layer 13A and 13B. The second photoresist pattern 15 is formed by coating the upper surface of the etch target layer 11 including the protective layer 13A and 13B with a second photoresist layer and patterning the second photoresist layer in the type of lines and spaces through an exposure process and a development process. In particular, the second photoresist pattern 15 is formed in such a manner that the lines and spaces stretched in the second direction, which is the Y axial direction perpendicularly to the first direction, which is the X axial direction, are repeatedly arrayed.

During an exposure process for forming the second photoresist pattern 15, the protective layer 13A and 13B disposed under the second photoresist pattern 15 may prevent the formation of an abnormal pattern through the exposure process. Therefore, the formation of an abnormal hole pattern may be prevented and also, the etch target layer 11 may be protected from being etched through the abnormal hole pattern.

Subsequently, a hole pattern is formed by using the first photoresist pattern including the protective layer 13A and 13B formed on the surface and the second photoresist pattern 15 as etch barriers and etching the etch target layer 11.

The method for forming a mask for forming contact holes of a semiconductor device in accordance with an exemplary embodiment of the present invention forms a protective layer on the entire surface of a first photoresist pattern during a freezing process by forming the first photoresist pattern in lines and pads and removing a photoresist layer in all regions except the lines and pads so that the entire remaining first photoresist pattern may become a photo acid generation region.

Since the first photoresist pattern is not affected by an exposure process that is performed for forming a second photoresist pattern, the formation of an abnormal pattern may be prevented.

While the present invention has been described with respect to the specific embodiments, it will be apparent to those skilled in the art that various changes and modifications may be made without departing from the spirit and scope of the invention as defined in the following claims.

What is claimed is:

1. A method for forming a mask for forming contact holes of a semiconductor device, comprising:
coating an etch target layer with a first photoresist layer;
patterning the first photoresist layer in a type of lines and spaces to form a first photoresist pattern, wherein the first photoresist pattern comprises pads formed at both ends of the first photoresist pattern, and lines repeatedly formed between the pads at the both ends;
forming a protective layer on a surface of the first photoresist pattern by performing a freezing process onto the first photoresist pattern; and
forming a second photoresist pattern having a type of lines stretched in a second direction which is perpendicular to the first direction on the etch target layer including the protective layer.

2. The method of claim 1, wherein the forming of the protective layer comprises:
forming a freezing material layer over the etch target layer including the first photoresist pattern;
forming the protective layer on the surface of the first photoresist pattern through a baking process; and
removing the freezing material layer which is not formed as the protective layer.

3. The method of claim 2, wherein the freezing material layer is formed by applying a freezing agent which is formed of a resin and a cross-linker.

4. The method of claim 2, wherein the freezing material layer comprises a liquid polymer.

5. The method of claim 1, wherein the pads are patterned thicker than the lines.

6. The method of claim 1, wherein the width of the pads is controlled not to exceed at least twice a penetration range of the freezing material layer.

7. The method of claim 1, further comprising:
forming contact holes by using the first photoresist pattern and the second photoresist pattern as etch barriers and etching the etch target layer.

8. A method for forming a mask for forming contact holes of a semiconductor device, comprising:
forming a first photoresist pattern on an etch target layer, wherein the first photoresist pattern comprises pads formed at both ends of the first photoresist pattern, and the width of the pads is controlled to be equal to or less than twice a penetration range of the freezing material layer;
forming a protective layer on a surface of the first photoresist pattern; and
forming a second photoresist pattern having a type of lines stretched in a second direction which is perpendicular to the first direction on the etch target layer including the protective layer.

9. The method of claim 8, wherein the forming of a first photoresist pattern comprises:
coating the etch target layer with a first photoresist layer; and
patterning the first photoresist layer in a type of lines and spaces to form a first photoresist pattern, wherein the first photoresist pattern comprises the pads, and lines repeatedly formed between the pads at the both ends.

10. The method of claim 9, wherein the forming of the protective layer comprises:
forming a freezing material layer over the etch target layer including the first photoresist pattern;
forming the protective layer on the surface of the first photoresist pattern through a baking process; and
removing the freezing material layer which is not formed as the protective layer.

11. The method of claim 10, wherein the freezing material layer is formed by applying a freezing agent which is formed of a resin and a cross-linker.

12. The method of claim 10, wherein the freezing material layer comprises a liquid polymer.

13. The method of claim 9, wherein the pads are patterned thicker than the lines.

14. The method of claim 8, further comprising:
forming contact holes by using the first photoresist pattern and the second photoresist pattern as etch barriers and etching the etch target layer.
